(19) United States
(12) Patent Application Publication
(10) Pub. No.: US 2024/0283242 A1
(43) Pub. Date: Aug. 22, 2024

(54) SWITCH CONTROL DEVICE AND BATTERY PACK INCLUDING THE SAME

(71) Applicant: SAMSUNG SDI CO., LTD., Yongin-si (KR)

(72) Inventor: Kyusung CHO, Yongin-si (KR)

(21) Appl. No.: 18/488,812

(22) Filed: Oct. 17, 2023

(30) Foreign Application Priority Data
Feb. 22, 2023 (KR) 10-2023-0023771

(51) Int. Cl. H02H 11/00; H02J 7/00

(52) U.S. Cl. CPC H02H 11/005; H02J 7/0029; H02J 7/0063

(57) ABSTRACT

A switch control device according to the present disclosure may include a controller configured to output a control signal to control a switch, a low voltage protective circuit configured to generate an off signal for indicating an opening state of the switch when a voltage of a battery module is lower than a value in a state that the control signal indicates a closing state of the switch, and configured to maintain outputting of the off signal until the control signal indicates the opening state of the switch, and a switch driver configured to control the switch according to the control signal and the off signal, and to control the switch in the opening state regardless of the control signal when the off signal is received from the low voltage protective circuit.

### CROSS-REFERENCE TO RELATED APPLICATION

This application claims priority to, and the benefit of, Korean Patent Application No. 10-2023-0023771 filed in the Korean Intellectual Property Office on Feb. 22, 2023, the entire contents of which are incorporated herein by reference.

### BACKGROUND

### 1. Field

The present disclosure relates to a switch control device and a battery pack including the same.

### 2. Description of the Related Art

Recently, according to the strengthening of environmental regulations including CO₂ regulations, interest in environmentally friendly vehicles has been increasing. Accordingly, vehicle companies have been actively researching and developing pure electrical vehicles and hydrogen vehicles, as well as hybrid and plug-in hybrid vehicles.

A high voltage battery for storing electrical energy obtained from various energy sources is applied to the environmentally-friendly vehicles. A high voltage storage system of a vehicle uses high voltage electrical energy supplied from a high voltage battery for driving or electrical needs of the vehicle.

In the high voltage battery pack, the output of the high voltage battery pack may be transmitted to a load or cut off by a high voltage switch, such as a relay or a contactor. When the battery pack is aged, a transient situation may occur in which the battery voltage of the battery pack momentarily decreases and then rises again. When such a transient situation occurs, the high voltage switch operated by the battery voltage fails to maintain the closed state, then opens, and then becomes short-circuited again. This misoperation may cause a welding of the switch.

### SUMMARY

An aspect of the present disclosure provides a switch control device for improving a contact welding of a switch, and a battery pack including the same.

A switch control device according to the present disclosure may include a controller configured to output a control signal to control a switch, a low voltage protective circuit configured to generate an off signal for indicating an opening state of the switch when a voltage of a battery module is lower than a value in a state that the control signal indicates a closing state of the switch, and configured to maintain outputting of the off signal until the control signal indicates the opening state of the switch, and a switch driver configured to control the switch according to the control signal and the off signal, and to control the switch in the opening state regardless of the control signal when the off signal is received from the low voltage protective circuit.

The low voltage protective circuit may be further configured to block output of the off signal when the control signal indicates the opening state of the switch.

The low voltage protective circuit may include a comparison voltage generation circuit configured to supply, to a first node depending on the control signal, one of a first comparison voltage corresponding to the voltage of the battery module, or a second comparison voltage that maintains a fixed value regardless of the voltage of the battery module, a reference voltage generation circuit configured to supply a reference voltage to a second node, and a comparison circuit configured to control output of the off signal according to a comparison of the voltage of the first node and the voltage of the second node.

The comparison voltage generation circuit may be further configured to supply the first comparison voltage to the first node when the control signal indicates the closing state of the switch, and to supply the second comparison voltage to the first node when the control signal indicates the opening state of the switch, wherein the second comparison voltage is higher than the reference voltage, and wherein the first comparison voltage is lower than the reference voltage when the voltage of the battery module is lower than the value, and is higher than the reference voltage when the voltage of the battery module is higher than the value.

The comparison circuit may be further configured to control the off signal to be output to the switch driver when the first comparison voltage is lower than the reference voltage while the first comparison voltage is being supplied to the first node, and to maintain output of the off signal until the second comparison voltage is supplied to the first node.

The comparison circuit may be further configured to block the output of the off signal while the second comparison voltage is supplied to the first node.

The comparison circuit may be further configured to output an activation signal of a high level to output the off signal when the first comparison voltage is lower than the reference voltage while the first comparison voltage is supplied to the first node, output a deactivation signal of a low level to block the output of the off signal when the first comparison voltage is supplied to the first node and the first comparison voltage is higher than the reference voltage before the activation signal is output, and output the deactivation signal to block the output of the off signal when the second comparison voltage is supplied to the first node.

The comparison circuit may be further configured to transmit the voltage generated from output of the comparison circuit to the second node, wherein the voltage transmitted from the output of the comparison circuit to the second node is higher than the first comparison voltage and lower than the second comparison voltage when the comparison circuit outputs the activation signal.

The comparison voltage generation circuit may include a first transistor including a first terminal, a second terminal connected to ground, and a control terminal for receiving the control signal, a first resistor connected between the first node and a first power node to which the voltage of the battery module is applied, and a second resistor connected between the first node and the first terminal of the first transistor, wherein the first transistor is configured to be turned off when the control signal indicates the opening state of the switch, and is configured to be turned on when the control signal indicates the closing state of the switch, and wherein the first comparison voltage, which is distributed from the voltage of the battery module by the first resistor and the second resistor, is supplied to the first node when the first transistor is turned on.

The comparison voltage generation circuit may further include a first diode including an anode connected to the first node, and a cathode connected to a second power node, wherein the second comparison voltage is configured to be supplied to the first node by the first diode when the first transistor is turned off, and wherein the second comparison voltage is clamped from the voltage of the second power node by the first diode, and is higher than the first comparison voltage.

The first transistor may include an N-channel MOSFET(Metal Oxide Semiconductor Field Effect Transistor).

The reference voltage generation circuit may include a third resistor connected between the second power node and the second node, and a fourth resistor connected between the second power node and ground.

The comparison circuit may include a comparator including input terminals respectively connected to the first node and the second node, and an output terminal for outputting an output signal corresponding to a comparison of the voltage of the first node and the voltage of the second node, and a second diode including an anode connected to the output terminal of the comparator, and a cathode connected to the second node, wherein the comparison circuit is configured to transfer the voltage generated from the output signal of a high level to the second node through the second diode when the output signal of the high level is output to the output terminal of the comparator, and wherein the voltage generated from the output signal of the high level is higher than the first comparison voltage and the reference voltage, and is lower than the second comparison voltage.

The low voltage protective circuit may further include an off circuit configured to output the off signal to the switch driver according to the output signal of the comparison circuit.

The off circuit may include a second transistor including a control terminal for receiving the output signal of the comparator, a first terminal connected to an input terminal of the switch driver, and a second terminal connected to a ground, the second transistor being configured to connect the ground and the input terminal of the switch driver so that the off signal is transmitted to the input terminal of the switch driver.

The second transistor may include an NPN transistor.

The switch control device may further include a fifth resistor connected between an output terminal of the controller and the input terminal of the switch driver.

A battery pack according to one or more embodiments may include a battery module, a switch configured to control an electrical connection between the battery module and a load, and a switch control device configured to control the switch, and including a controller configured to output a control signal to control the switch, a low voltage protective circuit configured to generate an off signal for indicating an opening state of the switch when a voltage of the battery module is lower than a value in a state that the control signal indicates a closing state of the switch, and configured to maintain output of the off signal until the control signal indicates the opening state of the switch, and a switch driver configured to control the switch according to the control signal and the off signal, and to control the switch in the opening state regardless of the control signal when the off signal is received from the low voltage protective circuit.

The low voltage protective circuit may be further configured to block the output of the off signal when the control signal indicates the opening state of the switch.

The low voltage protective circuit may include a comparison voltage generation circuit configured to supply, to a first node depending on the control signal, one of a first comparison voltage corresponding to the voltage of the battery module, or a second comparison voltage that maintains a fixed value regardless of the voltage of the battery module, a reference voltage generation circuit configured to supply a reference voltage to a second node, and a comparison circuit configured to control the output of the off signal according to a comparison of the voltage of the first node and the voltage of the second node.

According to the present disclosure, it is possible to reduce or prevent the likelihood of the contact points of the switch being welled by blocking the switching of the switch back to the closing state in a transient situation.

### BRIEF DESCRIPTION OF THE DRAWINGS

FIG. 1 is a view schematically showing a switch control device according to one or more embodiments.

FIG. 2 is a view showing an example of a circuit configuration of a switch control device according to one or more embodiments.

FIG. 3 is a view schematically showing an operation timing diagram of a switch control device according to one or more embodiments.

FIG. 4 is a view schematically showing a battery pack including a switch control device according to one or more embodiments.

### DETAILED DESCRIPTION

Aspects of some embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may have various modifications and may be embodied in different forms, and should not be construed as being limited to only the illustrated embodiments herein. Further, each of the features of the various embodiments of the present disclosure may be combined or combined with each other, in part or in whole, and technically various interlocking and driving are possible. Each embodiment may be implemented independently of each other or may be implemented together in an association. The described embodiments are provided as examples so that this disclosure will be thorough and complete, and will fully convey the aspects of the present disclosure to those skilled in the art, and it should be understood that the present disclosure covers all the modifications, equivalents, and replacements within the idea and technical scope of the present disclosure. Accordingly, processes, elements, and techniques that are not necessary to those having ordinary skill in the art for a complete understanding of the aspects of the present disclosure may not be described.

Unless otherwise noted, like reference numerals, characters, or combinations thereof denote like elements throughout the attached drawings and the written description, and thus, descriptions thereof will not be repeated. Further, parts that are not related to, or that are irrelevant to, the description of the embodiments might not be shown to make the description clear.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

It will be understood that when an element, layer, region, or component is referred to as being “connected to,” or “(operatively or communicatively) coupled to” another element, layer, region, or component, it can be directly connected to, or coupled to, the other element, layer, region, or component, or indirectly connected to, or coupled to, the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled” refers to one component directly connecting or coupling another component without an intermediate component. Further, when a component or layer is described as being “between” two components or layers, it should be understood as only one component or layer between the two components or layers, or one or more other components or layers interposed between the same.

For the purposes of this disclosure, expressions such as “at least one of,” or “any one of,” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expression such as “at least one of A and B” and “at least one of A or B” may include A, B, or A and B. As used herein, “or” generally means “and/or,” and the term “and/or” includes any and all combinations of one or more of the associated listed items. For example, the expression such as “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

The terminology used herein is for the purpose of describing particular embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Some embodiments may be described in terms of functional block components and various processing steps. Such functional blocks may be realized by any number of hardware and/or software components configured to perform the specified functions. For example, the functional blocks of the disclosure may be implemented by one or more microcontrollers or circuit configurations for predetermined functions. The functional blocks of the disclosure may be implemented in a variety of programming or scripting languages. The functional blocks of the disclosure may be implemented as an algorithm running on one or more controllers. The functions performed by the function blocks of the disclosure may be performed by a plurality of function blocks, or the functions performed by the plurality of function blocks in the disclosure may be performed by one function block. In addition, the disclosure may employ the related art for electronic environment setting, signal processing, and/or data processing.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Hereinafter, a switch control device and a battery pack including the same according to one or more embodiments will be described in detail with reference to necessary drawings

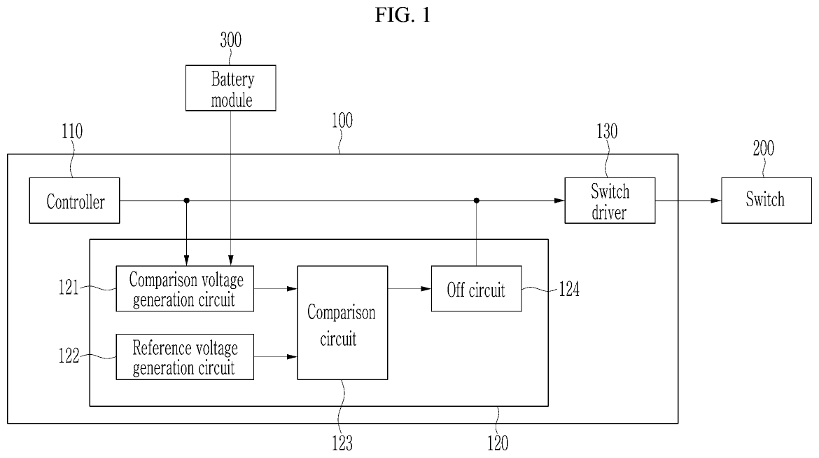

FIG. 1 is a view schematically showing a switch control device according to one or more embodiments.

Referring to FIG. 1, a switch control device 100 may include a controller 110, a low voltage protective circuit 120, and a switch driver 130.

The controller 110 may determine whether the switch 200 is opening/closing, and may output a control signal for controlling the switch 200. For example, the controller 110 may output a high level control signal to turn on (close) the switch 200, and a low level control signal to turn off (open) the switch 200. In this disclosure, the high level and the low level may indicate a voltage level that is higher than a corresponding voltage, and a voltage level that is lower than a corresponding voltage, respectively, based on a voltage (e.g., predetermined voltage). For example, the high level may represent an operation voltage (e.g., about 5V) of the controller 110 or a voltage close to the operation voltage, and the low level may represent a ground voltage 0V or a voltage close to the ground voltage.

The low voltage protective circuit 120 may receive a control signal from the controller 110. The low voltage protective circuit 120 may receive a voltage of the battery module 300 from the battery module 300 as an input. The battery module 300 may operate as a voltage source for supplying an operation voltage to the switch 200. The low voltage protective circuit 120 may monitor the voltage of the battery module 300 while the received control signal indicates the turned on (closed) state of the switch 200, and may continuously output the off signal to the switch driver 130 if the voltage of the battery module 300 drops below a value (e.g., predetermined value). The low voltage protective circuit 120 may block the output of the off signal if the received control signal indicates the off (opened) state of the switch 200.

The low voltage protective circuit 120 may include a comparison voltage generation circuit 121, a reference voltage generation circuit 122, a comparison circuit 123, and an off circuit 124.

The comparison voltage generation circuit 121 may receive the control signal from the controller 110, and may output a comparison voltage generated according to the received control signal to the comparison circuit 123 described later. The comparison voltage generation circuit 121, if the control signal indicates the turned on (closed) state of the switch 200 (e.g., if the level of the control signal is high level), may output a voltage (hereinafter referred to as a first comparison voltage) having a voltage value that is determined according to the output voltage of the battery module 300 as a comparison voltage. If the control signal indicates the turned off (open) state of the switch 200 (e.g., if the level of the control signal is low level), the comparison voltage generation circuit 121 may output a voltage (hereinafter referred to as a second comparison voltage) having a fixed voltage value regardless of the output voltage of the battery module 300 as a comparison voltage.

The reference voltage generation circuit 122 may output a reference voltage to the comparison circuit 123 described below.

The comparison circuit 123 may receive the comparison voltage and the reference voltage from the comparison voltage generation circuit 121 and the reference voltage generation circuit 122, respectively. The comparison circuit 123 may compare the comparison voltage and the reference voltage, and may control the activation of the off circuit 124, which is described later, according to the comparison result. For example, the comparison circuit 123 receives the first comparison voltage from the comparison voltage generation circuit 121, and if the first comparison voltage is lower than the reference voltage, the comparison circuit 123 may output the activation signal for activating the off circuit 124, which is described later, to the off circuit 124. Also, for example, if the first comparison voltage is received from the comparison voltage generation circuit 121 and the first comparison voltage remains higher state than the reference voltage, the comparison circuit 123 may output the activation signal to the off circuit 124 for deactivating the off circuit 124, which is described later. In addition, for example, the comparison circuit 123 may output, to the off circuit 124, the activation signal for deactivating the off circuit 124, which is described below, if the second comparison voltage is received from the comparison voltage generation circuit 121.

The comparison circuit 123 may further perform a latch function. If the activation signal is output from the comparison circuit 123 while the first comparison voltage is received, the comparison circuit 123 may maintain the output of the activation signal regardless of the voltage level of the first comparison voltage received thereafter. Then, if the second comparison voltage is received from the comparison voltage generation circuit 121, the comparison circuit 123 may stop outputting the activation signal, and may output the deactivation signal to the off circuit 124. The off circuit 124 may activate or deactivate the output of the off signal

according to the signal output from the comparison circuit 123. The off circuit 124 may output the off signal to the switch driver 130 if the activation signal is received from the comparison circuit 123. The off circuit 124 may stop outputting the off signal if the deactivation signal is received from the comparison circuit 123.

The switch driver 130 may control the switch 200 (e.g., a contactor, a relay, a transistor, etc.) to be in a turned on state (closed) or in a turned off state (opened) according to the control signal received from the controller 110. For example, the switch driver 130 may control the switch 200 to be in the turned on (closed) state if the control signal is at a high level, and control the switch 200 to be in turned off (opened) state if the control signal is at a low level.

The switch driver 130 may control the switch 200 to be in the turned off (opened) state regardless of the control signal received from the controller 110 while the off signal is received from the low voltage protective circuit 120.

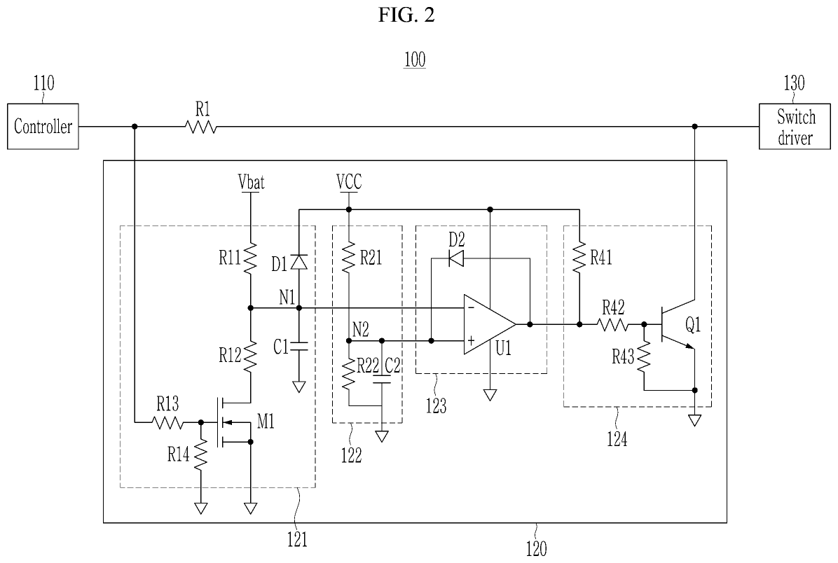

FIG. 2 is a view showing an example of a circuit configuration of the switch control device 100 according to one or more embodiments.

Referring to FIG. 2, the comparison voltage generation circuit 121 may include a transistor M1 connected to a ground, voltage distribution circuits R11 and R12 connected between the transistor M1 and a power node Vbat, and a diode D1 connected between the node N1 and another power node VCC.

The transistor M1 may include a first terminal connected to a resistor R12 of the voltage distribution circuit, a second terminal connected to the ground, and a control terminal connected to the output terminal of the controller 110. The resistor R11 of the voltage distribution circuit may be connected between the power node Vbat and a node N1, and the resistor R12 may be connected between the node N1 and the first terminal of transistor M1. The diode D1 may include an anode connected to the node N1, and a cathode connected to the power node VCC. The power node Vbat may be connected to a positive terminal of the battery module 300, and the other power node VCC may be connected to a voltage source for supplying the operation voltage to the controller 110 and to a comparator U1 described later. Accordingly, the output voltage of the battery module 300 may be supplied to the power node Vbat, and the operation voltage (e.g., 5V) of the comparator U1 may be supplied to the other power node VCC.

The comparison voltage generation circuit 121 may further include resistors R13 and R14 connected to the control terminal of the transistor M1 for the stable operation of the transistor M1. The comparison voltage generation circuit 121 may further include a capacitor C1 connected between the node N1 and the ground so that the voltage is stably supplied to the node N1.

The transistor M1 may be turned on or turned off according to the control signal received from the controller 110. The transistor M1 may be an N-channel metal oxide semiconductor field effect transistor (an N-channel MOSFET) of which the control terminal is a gate terminal, and the first terminal and the second terminal are a drain terminal and a source terminal, respectively. Therefore, the transistor M1 may be turned on if a voltage that is higher than a corresponding voltage (e.g., predetermined voltage) is applied to the control terminal, and turned off if a voltage that is lower than a corresponding voltage (e.g., predetermined voltage) is applied to the control terminal. That is, the transistor M1 may be turned on if the control signal is at a high level, and may be turned off if the control signal is at a low level.

If the transistor M1 is turned on, the voltage distribution circuits R11 and R12 may be electrically connected to the ground through the transistor M1. Therefore, if the transistor M1 is turned on, the resistors R11 and R12 may supply the voltage (the first comparison voltage) divided from the voltage of the power node Vbat, that is, the output voltage of the battery module 300, to the node N1. On the other hand, if the transistor M1 is turned off, the voltage (the second comparison voltage) clamped from the voltage of power node VCC may be supplied to the node N1 by the resistor R11 and the diode D1 that are connected between the power nodes Vbat and VCC.

The reference voltage generation circuit 122 may include voltage distribution circuits R21 and R22 connected between the power node VCC and the ground.

The resistor R21 may be connected between the power node VCC and the node N2, and the resistor R22 may be connected between the node N2 and the ground. Accordingly, the resistors R21 and R22 may supply the voltage (the reference voltage) divided from the voltage of the power node VCC, that is, the operation voltage of the comparator U1, to the node N2. The values of the resistors R21 and R22 may be set so that the reference voltage may be used to detect even over-discharge conditions as well as transient conditions. That is, the voltage value of the reference voltage may be set by the resistors R21 and R22 so that not only the transient state of the battery module 300, but also the over-discharge state of the battery module 300, may be detected in the comparison circuit 123 described later.

The reference voltage generation circuit 122 may further include a capacitor C2 connected between node N2 and ground so that the voltage is stably supplied to the node N2.

The comparison circuit 123 may include a latch circuit including a comparator U1 and a diode D2.

The comparator U1 may include input terminals respectively connected to the nodes N1 and N2, and an output terminal connected to the off circuit 124. The diode D2 may include an anode connected to the output terminal of comparator U1 and a cathode connected to node N2.

The comparator U1 may compare the voltage at the node N1 with the voltage at the node N2, and may determine the level of the output signal output to the off circuit 124 according to the comparison result. For example, the comparator U1 may have a negative input terminal connected to the node N1, and a positive input terminal connected to the node N2. In this case, if the voltage at node N2 is higher than the voltage at the node N1, the comparator U1 may output the output signal of the high level (e.g., about 5V). If the voltage at node N2 is lower than the voltage at node N1, the comparator U1 may output the output signal of the low level (e.g., about 0V). At this time, the output signal of the high level operates as the activation signal for activating the off signal output of the off circuit 124, and the output signal of the low level operates as the deactivation signal for inactivating the off signal output of the off circuit 124. If the output signal (the activation signal) of the high level is output from the comparator U1, the diode D2 transfers it to the node N2 so that the voltage of the node N2 may remain with the state that is higher than the voltage of the node N1. Accordingly, the comparator U1 may maintain the output of the output signal (the activation signal) of the high level.

In a state where the transistor M1 of the comparison voltage generation circuit 121 is turned off, the second comparison voltage that is higher than the voltage of power node VCC may be applied to the node N1 by the diode D1 regardless of the voltage of the battery module 300. Also, because the reference voltage applied to the node N2 by the reference voltage generation circuit 122 is a voltage divided from the voltage of the power node VCC, it may be a lower voltage than the voltage of the node N1. In addition, because the signal output of the high level from the comparator U1 corresponds to the voltage of the power node VCC, the voltage supplied to the node N2 by the diode D2 is higher than the voltage supplied to the node N2 by the voltage distribution circuits R21 and R22, but it may be lower than the second comparison voltage. Therefore, while the control signal indicates the turned off (opened) state of the switch 200 and the transistor M1 is turned off, regardless of the voltage of the battery module 300, the second comparison voltage applied to node N1 is higher than the voltage of node N2, so the comparator U1 may output the signal (the deactivation signal) of the low level.

In the state that the transistor M1 of the comparison voltage generation circuit 121 is turned on, the first comparison voltage distributed from the output voltage of the battery module 300 by the voltage distribution circuits R11 and R12 may be supplied to the node N1. The resistance values of the resistors R11 and R12 may be set so that if the output voltage of the battery module 300 is a threshold value or more, the first comparison voltage is higher than the reference voltage generated by the resistors R21 and R22 and lower than the voltage delivered to the node N2 from the output of the high level output from the comparator U1 through the diode D2. In addition, the resistance values of the resistors R11 and R12 may be set so that if the output voltage of the battery module 300 is lower than the threshold value, the first comparison voltage is lower than the reference voltage generated by the resistors R21 and R22. Therefore, in the state where the control signal indicates the turned on (closed) state of the switch 200 and the transistor M1 is turned on, if the output voltage of the battery module 300 is lower than the threshold value, the comparator U1 may output the signal (the activation signal) of the high level. After that, the comparator U1 maintains the output of the activation signal until the control signal indicates the turned off (opened) state of the switch 200, and if the control signal indicates the turned off (opened) state of the switch 200, it may output the signal (the deactivation signal) of the low level.

The off circuit 124 may include a transistor Q1.

The transistor Q1 may include a first terminal connected to the input terminal of the switch driver 130, a second terminal connected to the ground, and a control terminal connected to the output terminal of the comparator U1. The off circuit 124 may further include resistors R41, R42, and R43 connected to the control terminal of the transistor Q1 for the stable operation of the transistor Q1.

The transistor Q1 may be turned on if the activation signal is received from the comparator U1, and may be turned off if the deactivation signal is received from the comparator U1. For example, the transistor Q1 may be an NPN transistor in which a control terminal is a base terminal, and a first terminal and a second terminal are a collector terminal and an emitter terminal, respectively. In this case, the transistor Q1 may be turned on if the activation signal of the high level is input, and may be turned off if the deactivation signal of the low level is input. If the transistor Q1 is turned on, it may output the off signal corresponding to the ground voltage to the switch driver 130 by connecting the input terminal of the switch driver 130 to the ground.

The switch control device 100 may further include a resistor R1 connected between the output terminal of the controller 110 and the switch driver 130. Therefore, if the off signal of the low level is output from the off circuit 124 to the switch driver 130, even if the controller 110 outputs the control signal of the high level, the switch driver 130 may operate the switch 200 in the turned off (opened) state.

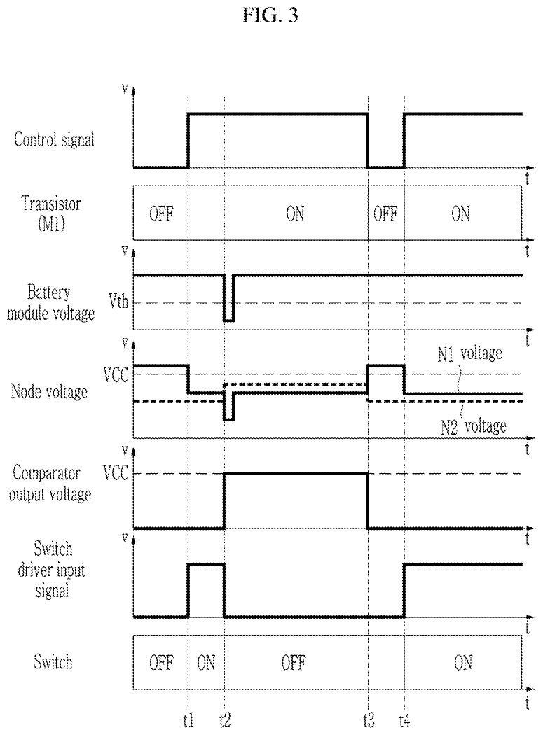

Hereinafter, the operation of the switch control device 100 according to one or more embodiments will be described in more detail with reference to FIG. 3.

FIG. 3 is a view schematically showing an operation timing diagram of the switch control device 100 according to one or more embodiments.

Referring to FIG. 3, as the control signal of the low level indicating the turned off (opened) state of the switch 200 is output from the controller 110 until a time t1, the transistor M1 of the comparison voltage generation circuit 121 becomes the turned off state, and thus, the second comparison voltage that is higher than the voltage of the power node VCC may be applied to the node N1 by the diode D1. In addition, a voltage distributed from the voltage of the power node VCC is applied to the node N2, and the comparator U1 may output the output signal (the inactive signal) of the low level. Accordingly, because the controller 110 has the right to control the switch 200, the switch 200 may be controlled in the turned off (opened) state in response to the control signal.

Then, as the control signal of the high level indicating the turned on (closed) state of the switch 200 is output from the controller 110 at the time t1, the transistor M1 of the comparison voltage generation circuit 121 is turned on, and as a result, the first comparison voltage distributed from the output voltage of the battery module 300 may be applied to the node N1. While the voltage of the battery module 300 is higher than the threshold value (Vth), the first comparison voltage is higher than the reference voltage applied to the node N2, so the comparator U1 may output the output signal of the low level (the inactive signal). Accordingly, because the controller 110 has the right to control the switch 200, the switch 200 may be controlled in the turned on (closed) state in response to the control signal.

On the other hand, at the time t2, a transient situation occurs, in which the voltage of the battery module 300 drops below the threshold value (Vth) and returns again. As a result, the first comparison voltage applied to the node N1 may be momentarily lower than the reference voltage applied to the node N2. Therefore, the comparator U1 outputs the output signal (activation signal) of the high level, and then the high level output of the comparator U1 may be continued by the diode D2. Accordingly, by activating the off circuit 124 and bringing the control right of the switch 200, the switch 200 may be controlled in a turned off (opened) state.

The activation signal output of the comparator U1 may continue until the control signal of the low level indicating the turned off (opened) state of the switch 200 is output from the controller 110 at a time t3. Therefore, the control right of the switch 200 may also be in the off circuit 124, not the controller 110, until the time t3.

At the time t3, if the control signal of the low level indicating the turned off (opened) state of the switch 200 is output from the controller 110, the second comparison voltage that is higher than the voltage of the power node VCC is applied to the node N1 by the diode D1, thereby the comparator U1 may output the output signal of the low level (the inactive signal). Therefore, the control right of the switch 200 passes to the controller 110, and the opening/closing of the switch 200 may be controlled in response to the control signal. For example, at the time of t4, the controller 110 may control the switch 200 in the turned on (closed) state by outputting the control signal of the high level.

According to the above-described, if the transient situation in which the voltage of the battery module 300 is momentarily lowered and then returns to the original state occurs while the controller 110 controls the switch 200 to be turned on (closed), the switch control device 100 may reduce or prevent the likelihood of the switch 200 being turned on (closed) again by taking the control right of the switch 200 from the controller 110. Therefore, it is possible to reduce or prevent the likelihood of the switch 200 unintentionally repeating the on/off state, thereby reducing or preventing the likelihood of a contact welding of the switch 200.

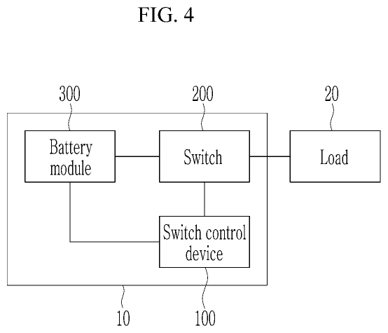

FIG. 4 is a view schematically showing a battery pack including a switch control device according to one or more embodiments.

Referring to FIG. 4, a battery pack 10 may include a switch control device 100, a switch 200, and a battery module 300.

The battery module 300 may include at least one cell connected in series or in parallel to each other.

The switch 200 may be connected between the battery module 300 and the load 20 to electrically connect the battery module 300 and the load 20, or to cut off the electrical connection between the battery module 300 and the load 20.

The switch control device 100 may control the opening/closing state of the switch 200. The switch control device 100, as described with reference to FIG. 1 and FIG. 2, may include the controller 110, the low voltage protective circuit 120, and the switch driver 130.

The controller 110 of the switch control device 100 may be a battery management system (BMS) of the battery pack 10. In this case, the controller 110 determines whether to open/close the switch 200 based on a status information of the battery module 300, a status information of the system (e.g., vehicle) equipped with the battery pack 10, a driving mode, etc., and may output the control signal to control the switch 200.

The drawings referred and the detailed description of the present disclosure disclosed up to now are just used for examples of the present disclosure, and are just used for the purpose of describing the present disclosure, but not used for limiting a meaning, or for restricting the scope of the present disclosure disclosed in the claims. Therefore, it will be appreciated by those skilled in the art that various modifications and other embodiments equivalent thereto can be made therefrom. Accordingly, the true technical scope of the present disclosure should be defined by the technical spirit of the appended claims, with functional equivalents thereof to be include therein.

Description of Some of the Reference Characters

| | |
|---|---|
| 10: battery pack | 20: load |
| 100: switch control device | 110: controller |
| 120: low voltage protective circuit | 121: comparison voltage |
| | generation circuit |
| 122: reference voltage generation circuit | |
| 123: comparison circuit | 124: off circuit |
| 130: switch driver | 200: switch |
| 300: battery module | |

What is claimed is:

1. A switch control device comprising:
a controller configured to output a control signal to control a switch;
a low voltage protective circuit configured to generate an off signal for indicating an opening state of the switch when a voltage of a battery module is lower than a value in a state that the control signal indicates a closing state of the switch, and configured to maintain outputting of the off signal until the control signal indicates the opening state of the switch; and
a switch driver configured to control the switch according to the control signal and the off signal, and to control the switch in the opening state regardless of the control signal when the off signal is received from the low voltage protective circuit.

2. The switch control device as claimed in claim 1, wherein the low voltage protective circuit is further configured to block output of the off signal when the control signal indicates the opening state of the switch.

3. The switch control device as claimed in claim 1, wherein the low voltage protective circuit comprises:
a comparison voltage generation circuit configured to supply, to a first node depending on the control signal, one of a first comparison voltage corresponding to the voltage of the battery module, or a second comparison voltage that maintains a fixed value regardless of the voltage of the battery module;
a reference voltage generation circuit configured to supply a reference voltage to a second node; and
a comparison circuit configured to control output of the off signal according to a comparison of the voltage of the first node and the voltage of the second node.

4. The switch control device as claimed in claim 3, wherein the comparison voltage generation circuit is further configured to supply the first comparison voltage to the first node when the control signal indicates the closing state of the switch, and to supply the second comparison voltage to the first node when the control signal indicates the opening state of the switch,
wherein the second comparison voltage is higher than the reference voltage, and
wherein the first comparison voltage is lower than the reference voltage when the voltage of the battery module is lower than the value, and is higher than the reference voltage when the voltage of the battery module is higher than the value.

5. The switch control device as claimed in claim 3, wherein the comparison circuit is further configured to control the off signal to be output to the switch driver when the first comparison voltage is lower than the reference voltage while the first comparison voltage is being supplied to the first node, and to maintain output of the off signal until the second comparison voltage is supplied to the first node.

6. The switch control device as claimed in claim 5, wherein the comparison circuit is further configured to block the output of the off signal while the second comparison voltage is supplied to the first node.

7. The switch control device as claimed in claim 5, wherein the comparison circuit is further configured to:
output an activation signal of a high level to output the off signal when the first comparison voltage is lower than the reference voltage while the first comparison voltage is supplied to the first node,
output a deactivation signal of a low level to block the output of the off signal when the first comparison voltage is supplied to the first node and the first comparison voltage is higher than the reference voltage before the activation signal is output, and
output the deactivation signal to block the output of the off signal when the second comparison voltage is supplied to the first node.

8. The switch control device as claimed in claim 7, wherein the comparison circuit is further configured to transmit the voltage generated from output of the comparison circuit to the second node, and
wherein the voltage transmitted from the output of the comparison circuit to the second node is higher than the first comparison voltage and lower than the second comparison voltage when the comparison circuit outputs the activation signal.

9. The switch control device as claimed in claim 3, wherein the comparison voltage generation circuit comprises:
a first transistor comprising a first terminal, a second terminal connected to ground, and a control terminal for receiving the control signal;
a first resistor connected between the first node and a first power node to which the voltage of the battery module is applied; and
a second resistor connected between the first node and the first terminal of the first transistor,
wherein the first transistor is configured to be turned off when the control signal indicates the opening state of the switch, and is configured to be turned on when the control signal indicates the closing state of the switch, and
wherein the first comparison voltage, which is distributed from the voltage of the battery module by the first resistor and the second resistor, is supplied to the first node when the first transistor is turned on.

10. The switch control device as claimed in claim 9, wherein the comparison voltage generation circuit further comprises a first diode comprising an anode connected to the first node, and a cathode connected to a second power node,
wherein the second comparison voltage is configured to be supplied to the first node by the first diode when the first transistor is turned off, and
wherein the second comparison voltage is clamped from the voltage of the second power node by the first diode, and is higher than the first comparison voltage.

11. The switch control device as claimed in claim 10, wherein the first transistor comprises an N-channel MOSFET(Metal Oxide Semiconductor Field Effect Transistor).

12. The switch control device as claimed in claim 10, wherein the reference voltage generation circuit comprises:
a third resistor connected between the second power node and the second node, and
a fourth resistor connected between the second power node and ground.

13. The switch control device as claimed in claim 3, wherein the comparison circuit comprises:
a comparator comprising input terminals respectively connected to the first node and the second node, and an output terminal for outputting an output signal corresponding to a comparison of the voltage of the first node and the voltage of the second node; and
a second diode comprising an anode connected to the output terminal of the comparator, and a cathode connected to the second node,
wherein the comparison circuit is configured to transfer the voltage generated from the output signal of a high level to the second node through the second diode when the output signal of the high level is output to the output terminal of the comparator, and
wherein the voltage generated from the output signal of the high level is higher than the first comparison voltage and the reference voltage, and is lower than the second comparison voltage.

14. The switch control device as claimed in claim 13, wherein the low voltage protective circuit further comprises an off circuit configured to output the off signal to the switch driver according to the output signal of the comparison circuit.

15. The switch control device as claimed in claim 13, wherein the off circuit comprises a second transistor comprising a control terminal for receiving the output signal of the comparator, a first terminal connected to an input terminal of the switch driver, and a second terminal connected to a ground, the second transistor being configured to connect the ground and the input terminal of the switch driver so that the off signal is transmitted to the input terminal of the switch driver.

16. The switch control device as claimed in claim 15, wherein the second transistor comprises an NPN transistor.

17. The switch control device as claimed in claim 15, further comprising a fifth resistor connected between an output terminal of the controller and the input terminal of the switch driver.

18. A battery pack comprising:
a battery module;
a switch configured to control an electrical connection between the battery module and a load; and
a switch control device configured to control the switch, and comprising:
a controller configured to output a control signal to control the switch;
a low voltage protective circuit configured to generate an off signal for indicating an opening state of the switch when a voltage of the battery module is lower than a value in a state that the control signal indicates a closing state of the switch, and configured to maintain output of the off signal until the control signal indicates the opening state of the switch; and
a switch driver configured to control the switch according to the control signal and the off signal, and to control the switch in the opening state regardless of the control signal when the off signal is received from the low voltage protective circuit.

19. The battery pack as claimed in claim 18, wherein the low voltage protective circuit is further configured to block the output of the off signal when the control signal indicates the opening state of the switch.

20. The battery pack as claimed in claim 18, wherein the low voltage protective circuit comprises:
a comparison voltage generation circuit configured to supply, to a first node depending on the control signal, one of a first comparison voltage corresponding to the voltage of the battery module, or a second comparison voltage that maintains a fixed value regardless of the voltage of the battery module;
a reference voltage generation circuit configured to supply a reference voltage to a second node; and
a comparison circuit configured to control the output of the off signal according to a comparison of the voltage of the first node and the voltage of the second node.
